(19) United States
(12) Patent Application Publication
(10) Pub. No.: US 2005/0214445 A1
(43) Pub. Date: Sep. 29, 2005

(54) Method and processing system for determining coating status of a ceramic substrate heater

(75) Inventors: Cory Wajda, Hopewell Junction, NY (US); David L. O'Meara, Poughkeepsie, NY (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: Tokyo Electron Limited, Tokyo (JP)

(21) Appl. No.: 10/811,574

(22) Filed: Mar. 29, 2004

(51) Int. Cl. B05C 11/00; C23C 16/00; B05D 1/00

(52) U.S. Cl. 427/8; 427/248.1; 118/665; 118/712

(57) ABSTRACT

A method and system for monitoring coating status of a ceramic substrate heater in a process chamber. The method includes heating a ceramic substrate heater to a desired temperature, exposing the ceramic substrate heater to a reactant gas during a process, and monitoring optical emission from the heated ceramic substrate heater to determine coating status of the ceramic substrate heater. Processes that can be monitored include a chamber cleaning process and a chamber conditioning process.

### FIELD OF THE INVENTION

The present invention relates to chamber processing and more particularly, to determining coating status of a ceramic substrate heater during a process performed in a processing system.

### BACKGROUND OF THE INVENTION

Many semiconductor fabrication processes are performed in processing systems such as plasma etch systems, plasma deposition systems, thermal processing systems, chemical vapor deposition systems, atomic layer deposition systems, etc. Processing systems can use a ceramic substrate heater that supports and provides heating of a substrate (e.g., a wafer). Ceramic substrate heater materials can provide low thermal expansion, high temperature tolerance, a low dielectric constant, high thermal emissivity, a chemically “clean” surface, rigidity, and dimensional stability that makes them preferred heater materials for many semiconductor applications. Common ceramic materials for use in ceramic substrate heaters include alumina (Al₂O₃), aluminum nitride (AlN), silicon carbide (SiC), beryllium oxide (BeO), and lanthanum boride (LaB₆).

Processing of substrates in a processing system can result in formation of a material coating on a substrate heater and other system components that are exposed to the process environment. Periodic chamber cleaning is carried out to remove the material deposits from the system components. A dry cleaning process can be carried out using an approach where the length of the cleaning process is based on a fixed time period that has been proven to result in adequate cleaning of the system components. However, because the cleaning process is not actually monitored, the fixed time period may be unnecessarily long and result in undesired etching (erosion) of the system components.

Chamber conditioning processes (also referred to as passivation processes) are commonly implemented in semiconductor fabrication to prepare processing systems for optimal performance. For example, chamber conditioning processes may be carried out following chamber cleaning, after an extended chamber idle period, or before a first chamber production process. Chamber conditioning processes can help ensure that all production processes performed in a processing system produce results within a desired range. The extent of conditioning can be carried out for a fixed time period that has been proven to provide production process compliance. However, because the effectiveness of the conditioning process is not actually monitored, the fixed time period may be unnecessarily long in order to account for varying conditioning times required to achieve process compliance for different runs of a conditioning process. This can result in unacceptable reduction in throughput or productive tool time for the processing system.

### SUMMARY OF THE INVENTION

A method is provided for determining coating status of a ceramic substrate heater in a processing system by heating the ceramic substrate heater to a desired temperature, exposing the ceramic substrate heater to a reactant gas during a process, monitoring optical emission from the heated ceramic substrate heater to determine coating status of the ceramic substrate heater, and based upon the status from the monitoring, performing one of the following: (a) continuing the exposing and monitoring, and (b) stopping the process. The process can include a chamber cleaning process or a chamber conditioning process.

A processing system is provided that contains a ceramic substrate heater within a process chamber, a gas injection system configured for exposing the ceramic substrate heater to a reactant gas during a process, an optical monitoring system for monitoring optical emission from the ceramic substrate heater and to transmit the emission intensity, and a controller configured for receiving the emission intensity to determine coating status of the ceramic substrate heater, and configured for controlling the processing system in response to the status.

### BRIEF DESCRIPTION OF THE DRAWINGS

In the drawings:

FIG. 1 shows a schematic diagram of a processing system in accordance with an embodiment of the invention;

FIGS. 2A-2C show schematic cross-sectional views of a ceramic substrate heater in accordance with an embodiment of the invention;

FIG. 3 is a graph showing optical emission intensity as a function of processing time for monitoring coating status of a ceramic substrate heater during a cleaning process in accordance with an embodiment of the invention;

FIGS. 4A-4B show schematic cross-sectional views of a ceramic substrate heater in accordance with an embodiment of the invention;

FIG. 5 is a graph showing optical emission intensity as a function of processing time for monitoring coating status of a ceramic substrate heater during a conditioning process in accordance with an embodiment of the invention; and

FIG. 6 is a flowchart showing a method of monitoring coating status of a ceramic system heater in accordance with an embodiment of the invention.

### DETAILED DESCRIPTION OF SEVERAL EMBODIMENTS OF THE INVENTION

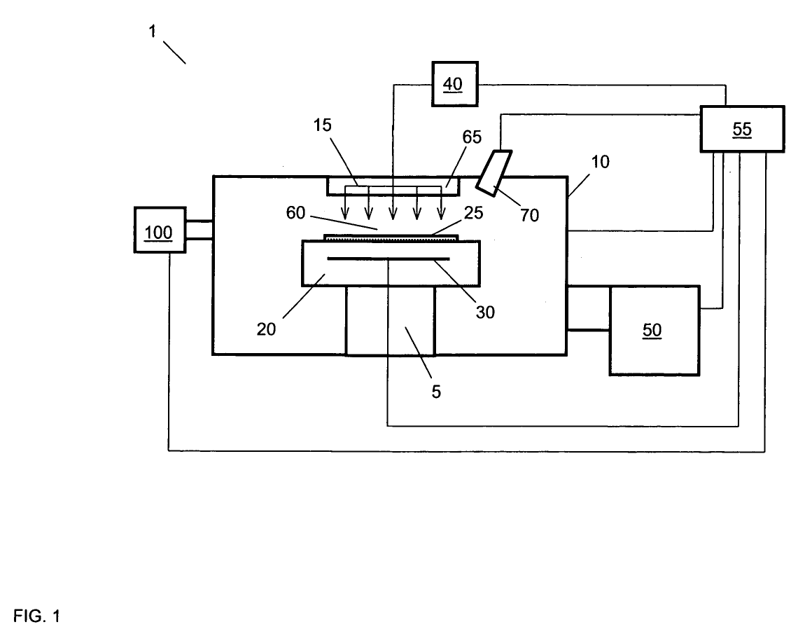

FIG. 1 shows a schematic diagram of a processing system in accordance with an embodiment of the invention. The processing system 1 includes a process chamber 10 having a pedestal 5 for mounting a ceramic substrate heater 20 for supporting and heating a substrate 25, a gas injection system 40 for introducing a process gas 15 to the process chamber 10, and a vacuum pumping system 50. The process gas 15 can, for example, be a reactant gas for cleaning or conditioning the substrate heater 20 and other system components in the process chamber 10, or a gas for processing the substrate 25. The gas injection system 40 allows independent control over the delivery of process gas 15 to the process chamber 10 from ex-situ gas sources (not shown). Gases can be introduced into the process chamber 10 via the gas injection system 40 and the chamber pressure adjusted. Controller 55 is used to control the vacuum pumping system 50 and gas injection system 40.

Substrate 25 is transferred into and out of chamber 10 through a slot valve (not shown) and chamber feed-through (not shown) via a robotic substrate transfer system 100 where it is received by substrate lift pins (not shown) housed within substrate heater 20 and mechanically translated by devices housed therein. Once the substrate 25 is received from the substrate transfer system, it is lowered to an upper surface of the substrate heater 20.

In one configuration, the substrate 25 can be affixed to the substrate heater 20 via an electrostatic clamp (not shown). Furthermore, the substrate heater 20 can further include a cooling system including a re-circulating coolant flow that receives heat from the substrate heater 20 and transfers heat to a heat exchanger system (not shown). Moreover, gas may be delivered to the backside of the substrate to improve the gas-gap thermal conductance between the substrate 25 and the substrate heater 20. Such a system is utilized when temperature control of the substrate is required at elevated or reduced temperatures.

The substrate heater 20 can be a ceramic substrate heater containing a heating element 30 and a thermocouple (not shown) for measuring the temperature of the heater body. The heating element 30 can, for example, be a resistive heating element. One example of a ceramic substrate heater is an AlN heater for processing 300 mm wafers, manufactured by Sumitomo Electric Limited, Tokyo, Japan. The processing system 1 contains an optical monitoring system 70 for monitoring optical emission from the substrate holder 20 (and from a substrate 25 when present on the substrate holder 20).

Continuing reference to FIG. 1, process gas 15 is introduced to the processing region 60 from the gas injection system 40. The process gas 15 can be introduced to the processing region 60 through a gas injection plenum (not shown), a series of baffle plates (not shown) and a multi-orifice showerhead gas injection plate 65. Vacuum pump system 50 can include a turbo-molecular vacuum pump (TMP) capable of a pumping speed up to 5,000 liters per second (and greater), and a gate valve for throttling the chamber pressure.

The controller 55 includes a microprocessor, a memory, and a digital I/O port capable of generating control voltages sufficient to communicate and activate inputs to the processing system 1 as well as monitor outputs from the processing system 1. Moreover, the controller 55 is coupled to and exchanges information with the process chamber 10, gas injection system 40, optical monitoring system 70, heating element 30, substrate transfer system 100, and vacuum pump system 50. For example, a program stored in the memory can be utilized to control the aforementioned components of a processing system 1 according to a stored process recipe. One example of controller 55 is a digital signal processor (DSP); model number TMS320, available from Texas Instruments, Dallas, Tex.

In FIG. 1, optical monitoring system 70 may be configured for monitoring infrared optical emission from the substrate heater 30 and may include a radiation thermometer, commonly called a pyrometer. Pyrometers are well-known to artisans skilled in the art of semiconductor processing.

A pyrometer can include an optical probe connected to a light pipe that samples the emitted infrared radiation with wavelengths about 1 μm from an object, for computing the temperature of the object emitting the radiation based on the emissivity of the object and the ideal black-body radiation-temperature relationship. Optical pyrometry can be a non-invasive temperature measurement technology and allows relatively fast in-situ temperature measurements.

Accurate temperature measurements of an object using optical pyrometry depend on the emitting characteristics or emissivity of the object. Most objects are not black body emitters, and emit some fraction of the amount that a black body would. For example, if an object emits 0.5 as much radiation at a given wavelength and temperature as a black body, the object is said to have an emissivity of 0.5. Emissivity of a ceramic substrate heater can depend on several parameters, including heater temperature, heater material, surface roughness of heater, and any material coating formed on the heater surface (including the type and thickness of the material coating). The formation of a material coating on a ceramic substrate heater can dynamically change the emissivity of the heater surface. A very thin material coating on the heater surface can affect the emissivity value of the surface and (depending on the coating thickness) the correct emissivity value may be that of the coating, not the heater material. Furthermore, very thin coatings can act as “interference filters” that cause the emissivity to vary widely depending on the exact coating thickness.

The present invention utilizes changes in the emissivity of a ceramic substrate heater, due to a material coating, for determining coating status of the ceramic substrate heater. As described above, an optical monitoring system such as a pyrometer can be used to monitor optical emission from the substrate heater (or from a substrate supported by the substrate heater). Monitoring of infrared optical emission in the present invention can prevent unnecessarily long cleaning times and undesirable erosion of the heater, or prevent excessive conditioning of the heater during a conditioning process.

The type of material coating formed on system components in a processing system depends on the processes that are carried out in the processing system. A coating can be from a few angstrom to several hundred angstrom thick, or thicker, and can contain one or more type of materials, for example silicon-containing materials such as silicon (Si), silicon germanium (SiGe), silicon nitride (SiN), silicon dioxide (SiO₂), or doped Si; dielectric materials including high-k metal oxides such as HfO₂, HfSiOₓ, ZrO₂, ZrSiOₓ; metals (e.g., Ta, Cu, Ru), metal oxides (e.g., Ta₂O₅, CuOₓ, RuO₂), or metal nitrides (e.g., TaN).

The presence of a substrate on a substrate heater during processing can reduce formation of a material coating onto the substrate heater surface underneath the substrate. This partial coating of the substrate heater material can lead to non-uniform heater temperature due to varying emissivity of the substrate heater surfaces. Ceramic substrate materials, such as AlN, often have high emissivity values, whereas material coatings containing metals, metal oxides, and metal nitrides, tend to have lower emissivity values.

Coating status of a ceramic substrate heater can, for example, indicate the relative amount of a material coating remaining on the substrate heater surface during a chamber cleaning process where a material coating is being removed from the substrate heater, or a relative amount of a material coating formed on the substrate heater surface during a chamber conditioning process.

In one embodiment of the invention, a method is provided for monitoring coating status of a ceramic substrate heater during a cleaning process. The cleaning process can include exposing the ceramic substrate heater to a reactant gas capable of removing a material coating from the heater surface. In one embodiment of the invention, the reactant gas can, for example, include a halogen-containing gas (e.g., CIF₃, F₂, NF₃ and HF). The reactant gas can further contain an inert gas selected from at least one of Ar, He, Ne, Kr, Xe, and N₂.

Monitoring optical emission from a substrate heater during a cleaning process can further include determining if the intensity level of the optical emission has reached a threshold value, indicating that removal of the material coating is complete, or nearing completion, thereby arriving at a determination of whether the substrate heater has been sufficiently cleaned, and based on the determination, either continuing with the cleaning process or stopping the cleaning process.

In another embodiment of the invention, a method is provided for monitoring coating status of a ceramic substrate heater during a conditioning process. The conditioning process can include exposing the ceramic substrate heater to a reactant gas capable of forming a material coating on the heater surface. The reactant gas can, for example, include a silicon-containing gas such as dichlorosilane (SiH₂Cl₂) and a nitrogen-containing gas such as ammonia (NH₃) to form a silicon nitride (SiN) coating on a substrate heater to passivate and prevent contaminant outgassing. Alternatively, the reactant gas can contain a metal-containing precursor to deposit a metal, a metal oxide, or a metal nitride on the substrate heater. The reactant gas can further contain an inert gas selected from at least one of Ar, He, Ne, Kr, Xe, and N₂. A substantially uniform material coating on the heater surface can improve temperature uniformity of a substrate and prevent mechanical failure of the ceramic heater material.

Monitoring optical emission from a substrate heater during a chamber conditioning process can further include determining if the intensity level of the optical emission has reached a threshold value, indicating that the conditioning process is complete, or nearing completion, thereby arriving at a determination of whether the substrate heater has been sufficiently conditioned, and based on the determination, either continuing with the conditioning process or stopping the conditioning process.

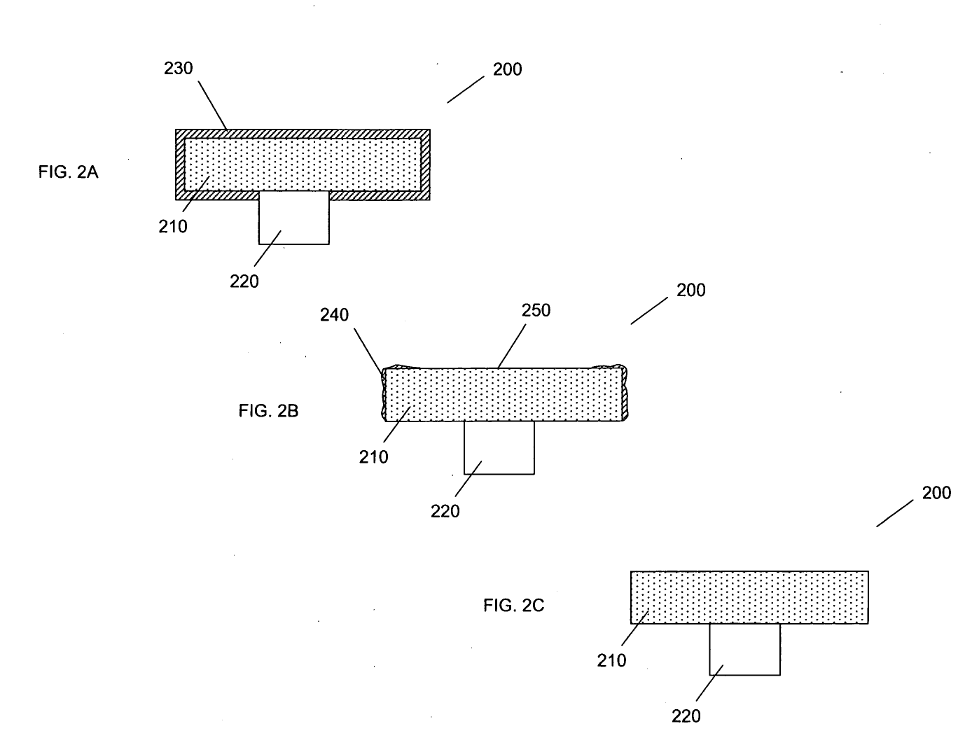

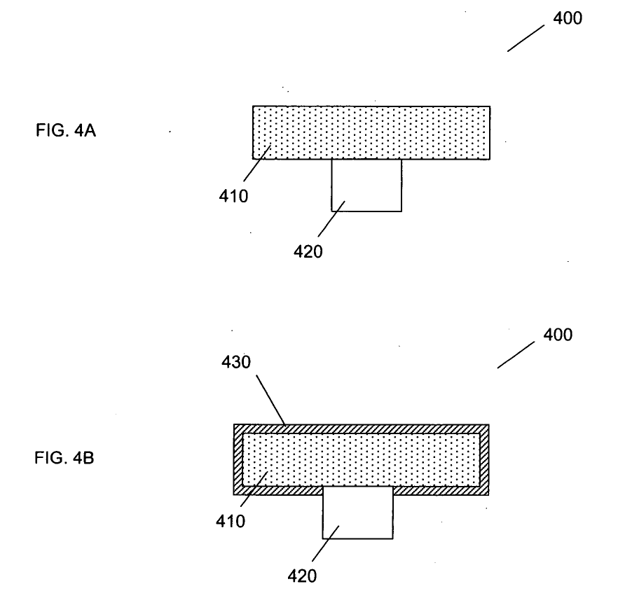

Even though a substrate is not shown on the substrate heater in FIGS. 2 and 4, discussed below, it is to be understood that according to the present invention, a substrate can be present on the ceramic substrate heater during a cleaning process or a conditioning process. Due to the corrosive process environment that is present during a cleaning process or a conditioning process, it may be desirable to place a substrate on the ceramic substrate heater to protect the heater.

FIGS. 2A-2C show schematic cross-sectional views of a ceramic substrate heater in accordance with an embodiment of the invention. The ceramic substrate heater 200 contains heater material 210 that is supported by pedestal 220. The ceramic substrate heater can be manufactured from a variety of materials, for example Al₂O₃, AlN, SiC, BeO, and LaB₆. The heater material 210 in FIG. 2A has a continuous smooth material coating 230 thereon. In FIG. 2B, the ceramic substrate heater 200 has a non-uniform material coating 240 that only partly covers the heater material 210. In particular, heater surface 250 that supports a substrate during a production process can be substantially free of a material coating. FIG. 2C schematically shows a cross-sectional view of a clean ceramic substrate heater 200 in accordance with an embodiment of the invention. FIG. 2C depicts a clean substrate heater 200 that is free of a material coating, as a result of a chamber cleaning process, where a material coating (e.g., the material coatings in FIGS. 2A and 2B), has been removed in a dry cleaning process by exposing the ceramic substrate heater 200 to a reactant gas.

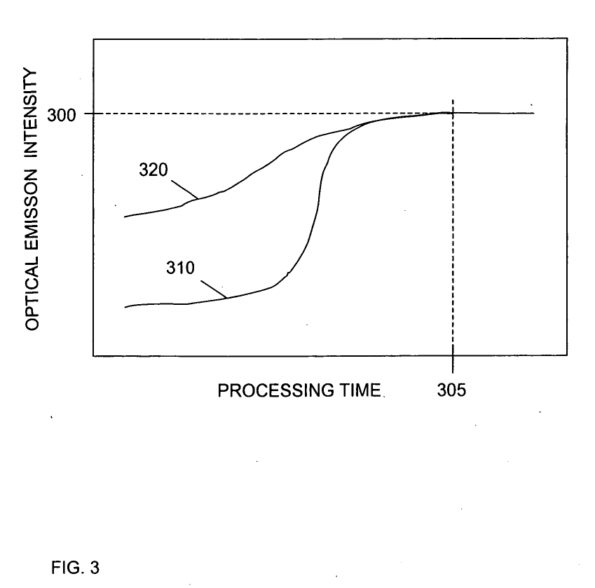

FIG. 3 is a graph showing optical emission intensity as a function of processing time for monitoring coating status of a ceramic substrate heater during a cleaning process in accordance with an embodiment of the invention. The dry cleaning process exposes a ceramic substrate heater containing a material coating to a reactant gas capable of removing the material coating. The measured optical emission intensity may be the output of a pyrometer. In curves 310 and 320, the optical emission intensity generally increases during the cleaning process to an asymptotic intensity value 300, due to removal of a material coating (with low emissivity) from the heater and uncovering of the ceramic heater material (with high emissivity). In general, the exact shape of the signal intensity curves can depend on the amount, type, thickness, surface coverage of the material coating, and the characteristics of the cleaning process. Curve 310 may be observed during cleaning of a substrate heater having a substantially uniform material coating (e.g., FIG. 2A), where the optical emission intensity shows an abrupt increase and becomes saturated at complete removal of the coating material. Curve 320 may be observed during cleaning of a substrate heater having a non-uniform material coating (e.g., FIG. 2B), where the optical emission intensity shows a less abrupt increase during removal of the coating material.

Still referring to FIG. 3, threshold intensity 300 may be detected at time 305 when the ceramic substrate heater surface is known to be at an acceptable clean level for a desired production process. Due to the reactive nature of cleaning gases, if the cleaning process is carried out past time 305, erosion of the ceramic substrate material can occur. It is to be understood that an acceptable clean level may vary depending on the production process performed in the chamber. Furthermore, detection of the threshold intensity 300 at time 305 is generally not expected to vary significantly with the exact shape of the optical emission intensity curve.

An increase in optical emission intensity as a function of processing time during a cleaning process, as shown in FIG. 3, is expected when a low emissivity material coating is being removed from a high emissivity heater material. Alternatively, if a material coating has higher emissivity than the underlying heater material, a decrease in the optical emission intensity is expected during a cleaning process.

FIGS. 4A-4B show schematic cross-sectional views of a ceramic substrate heater in accordance with an embodiment of the invention. The clean ceramic substrate heater 400 in FIG. 4A is exposed to a reactant gas in a conditioning process to form a material coating on the surface of the substrate heater material 410. FIG. 4B schematically shows a cross-sectional view of a ceramic substrate heater 400 containing a material coating 430. The material coating 430 may contain a single layer or, alternately, it may contain multiple layers.

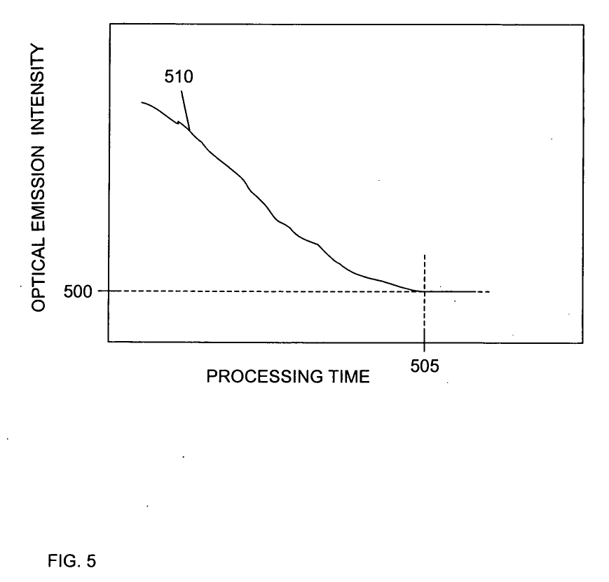

FIG. 5 is a graph showing optical emission intensity as a function of processing time for monitoring coating status of a ceramic substrate heater during a conditioning process in accordance with an embodiment of the invention. The conditioning process exposes a clean ceramic substrate heater to a reactant gas capable of forming a material coating on the heater. The measured signal intensity may be the output of a pyrometer. In curve 510, the optical emission intensity generally decreases during the conditioning process to an asymptotic intensity value 500, due to formation of a low emissivity material coating on the high emissivity ceramic heater material. In general, the exact shape of the optical emission intensity curve can depend on the amount, type, thickness, surface coverage of the material coating, and the characteristics of the conditioning process.

A threshold optical emission intensity 500 may be detected at time 505 when the ceramic substrate heater is known to be at an acceptable conditioning level for a desired manufacturing process. Carrying out the conditioning process beyond time 505 may be unnecessary and can result in unacceptable reduction in throughput for the processing system. It is to be understood that an acceptable conditioning level may vary depending on the production process performed in the chamber. Furthermore, detection of the threshold intensity 500 at time 505 is generally not expected to vary significantly with the exact shape of the optical emission intensity curve.

A decrease in optical emission intensity as a function of processing time during a conditioning process, as shown in FIG. 5, is expected when a low emissivity material coating is being formed onto a high emissivity heater material. Alternatively, if a material coating has higher emissivity than the underlying heater material, an increase in the optical emission intensity is expected during a conditioning process.

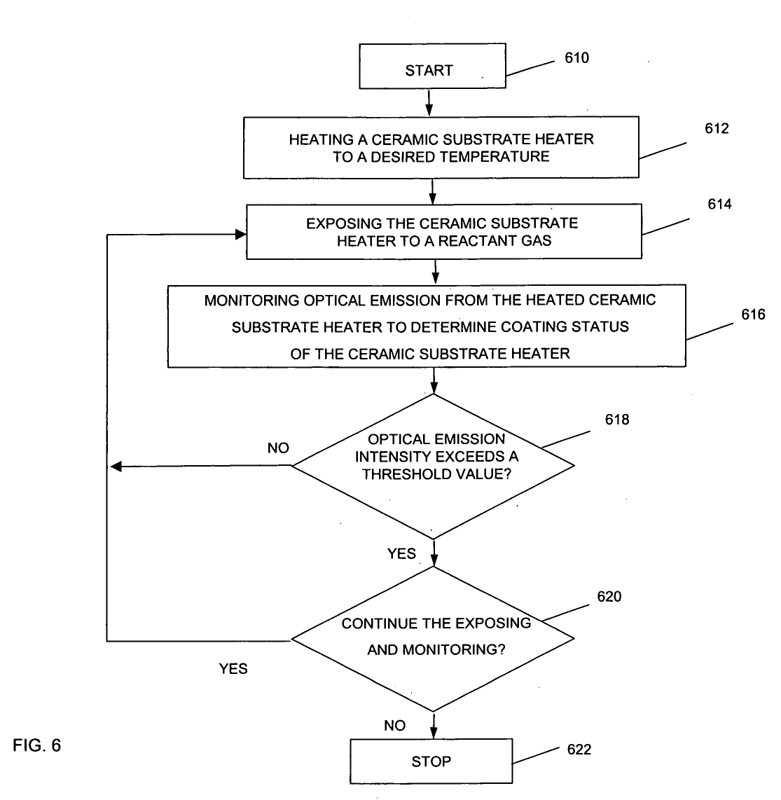

FIG. 6 is a flowchart showing a method of monitoring coating status of a ceramic substrate heater in accordance with an embodiment of the invention. At 610, the process is started. The process may be a cleaning process or a conditioning process that is performed in a process chamber and affects coating status of a ceramic substrate heater. At 612, a ceramic substrate heater is heated to a desired temperature. The temperature can, for example, range from about 400° C. to about 1000° C. At 614, the ceramic substrate heater is exposed to a reactant gas. At 616, optical emission from the ceramic substrate heater is monitored using an optical monitoring system to determine coating status of the ceramic substrate heater. At 618, if the optical emission intensity has reached a threshold value, a decision is made at 620 whether to continue the process or to stop the process at 622.

Determining whether the process should be continued in 620 can depend on the production process to be performed in the chamber. Correlation of the optical emission intensity to an endpoint of a cleaning or conditioning process can be carried out by test process that is performed while monitoring optical emission intensity and coating status of a ceramic substrate heater. Coating status of a ceramic substrate heater can, for example, be evaluated by inspecting the heater during the test process and correlating the inspected results to a detected threshold intensity recorded when a desired endpoint of the process is observed. The threshold intensity may be a fixed intensity value, or a ratio of the optical emission intensity and an initial optical emission intensity measured at the start of the process.

One example of a conditioning process is the formation of a low-emissivity Ru-containing coating on a high-emissivity AlN substrate heater. The Ru-containing coating can include Ru, RuSiₓ, and RuSiₓO_{y}, and can be formed by exposing the heater to Ru₃(CO)₁₂, Ru₃(CO)₁₂ and SiH₄, and Ru₃(CO)₁₂, SiH₄, and O₂, respectively, at a heater temperature of about 400° C., or higher. Alternatively, the Ru-containing coating can include alternating Ru and Si layers formed on the substrate heater. The conditioning process can be monitored according to the current invention (e.g., see FIGS. 5 and 6). The Ru-containing coating can subsequently be removed in a cleaning process and monitored according to the current invention (e.g., see FIGS. 3 and 6) using a halogen-containing gas.

Obviously, numerous modifications and variations of the present invention are possible in light of the above teachings. It is therefore to be understood that within the scope of the appended claims, the invention may be practiced otherwise that is specifically described herein. For example, the process steps described herein and recited in the claims may be performed in a sequence other than the sequence in which they are described or listed herein. As should be understood by one of ordinary skill in the art, only those process steps necessary to the performance of a later process step are required to be performed before the later process step is performed.

1. A method of determining coating status of a ceramic substrate heater in a processing system, the method comprising:
heating the ceramic substrate heater to a desired temperature;
exposing the ceramic substrate heater to a reactant gas during a process;
monitoring optical emission from the heated ceramic substrate heater to determine coating status of the ceramic substrate heater; and
based upon the status from the monitoring, performing one of the following: (a) continuing the exposing and monitoring, and (b) stopping the process.

2. The method according to claim 1, wherein the exposing comprises exposing the ceramic substrate heater to a cleaning gas for removing a material coating from the ceramic substrate heater in a chamber cleaning process.

3. The method according to claim 1, wherein the exposing comprises exposing the ceramic substrate heater to a conditioning gas for forming a material coating on the ceramic substrate heater in a chamber conditioning process.

4. The method according to claim 1, wherein the monitoring comprises detecting infrared optical emission.

5. The method according to claim 1, wherein the monitoring comprises comparing the optical emission intensity to a threshold value, the threshold value being a fixed intensity value or a ratio of the optical emission intensity and an initial optical emission intensity.

6. The method according to claim 1, wherein the performing (b) comprises stopping the process after a threshold value has been reached.

7. The method according to claim 1, wherein the heating comprises heating a ceramic substrate heater supporting a substrate.

8. A method of determining coating status of a ceramic substrate heater in a processing system, the method comprising:
determining a threshold value of an optical emission intensity for the ceramic substrate heater;
heating the ceramic substrate heater to a desired temperature;
exposing the heated ceramic substrate heater to a reactant gas during a process;
monitoring a measured value of optical emission from the heated ceramic substrate heater during the process and comparing the measured value to the threshold value to determine coating status of the ceramic substrate heater; and
stopping the process when the measured value is approximately equal to the threshold value.

9. The method according to claim 8, wherein determining the threshold value includes determining the optical emission intensity of the ceramic substrate heater having no coating formed thereon, and wherein the exposing comprises exposing the heated ceramic substrate heater having a material coating formed thereon to a cleaning gas for removing the material coating in a chamber cleaning process.

10. The method according to claim 8, wherein determining the threshold value includes determining the optical emission intensity of the ceramic substrate heater having a desired passivating coating formed thereon, and wherein the exposing comprises exposing the heated ceramic substrate heater having no desired passivating coating formed thereon to a reactant gas for forming the desired passivating coating in a chamber conditioning process.

11. A processing system, comprising:
a ceramic substrate heater within a process chamber;
a gas injection system configured for exposing the ceramic substrate heater to a reactant gas during a process;
an optical monitoring system configured for monitoring optical emission from the ceramic substrate heater and to transmit the emission intensity; and
a controller configured for receiving the emission intensity to determine coating status of the ceramic substrate heater, and configured for controlling the processing system in response to the status.

12. The processing system according to claim 11, wherein the gas injection system is configured for exposing the ceramic substrate heater to a cleaning gas for removing a material coating from the ceramic substrate heater in a cleaning process.

13. The processing system according to claim 11, wherein the gas injection system is configured for exposing the ceramic substrate heater to a conditioning gas for forming a material coating from the ceramic substrate heater in conditioning process.

14. The processing system according to claim 11, wherein the optical monitoring system comprises a pyrometer for detecting infrared radiation.

15. The processing system according to claim 11, wherein the controller is configured for comparing the optical emission intensity to a threshold value, the threshold value being a fixed intensity value or a ratio of the optical emission intensity and an initial optical emission intensity.

16. The processing system according to claim 15, wherein the controller is further configured for performing one of the following: (a) continuing the exposing and monitoring, and (b) stopping the process.

17. The processing system according to claim 11, wherein the ceramic substrate heater comprises at least one of Al₂O₃, AlN, SiC, BeO and LaB₆.

18. The processing system according to claim 11, wherein the ceramic substrate heater further comprises a material coating containing at least one of a silicon-containing coating, a high-k coating, a metal coating, a metal oxide coating, and a metal nitride coating.

19. The processing system according to claim 11, wherein the ceramic substrate heater supports a substrate.
